(19) United States
(12) Patent Application Publication
(10) Pub. No.: US 2010/0051340 A1
(43) Pub. Date: Mar. 4, 2010

(54) DIELECTRIC PASTE HAVING A LOW DIELECTRIC LOSS, METHOD OF MANUFACTURE THEREOF AND AN ARTICLE THAT USES THE SAME

(75) Inventors: Yoo Seong YANG, Daejeon (KR); Eun Sung LEE, Seoul (KR)

Correspondence Address: CANTOR COLBURN, LLP, 20 Church Street, 22nd Floor, Hartford, CT, 06103, US

(73) Assignees: Samsung Electronics Co., Ltd., Suwon-si (KR); Samsung Electro-Mechanics Co., Ltd., Suwon-si (KR)

(21) Appl. No.: 12/369,401

(22) Filed: Feb. 11, 2009

(30) Foreign Application Priority Data
Sep. 4, 2008 (KR) 10-2008-0087271

(51) Int. Cl. H05K 1/16; H01B 3/40; H01B 1/24; H01G 9/00

(52) U.S. Cl. 174/260; 523/400; 252/511; 523/466; 361/500; 977/742; 977/932

(57) ABSTRACT

A dielectric paste having low dielectric loss is disclosed. The dielectric paste includes (A) a thermosetting resin; (B) an acid anhydride-based curing agent; (C) high dielectric constant particles; (D) an amine-based catalyst; and (E) a material for forming a salt with the amine-based catalyst (D). In the dielectric paste, the material (E) for forming a salt with the amine-based catalyst (D) is used so that the catalyst may be introduced in the form of a salt thus preventing the catalyst from binding with the high dielectric constant particles, thereby prohibiting the poisoning of the catalyst.

### CROSS-REFERENCE TO RELATED APPLICATION

This application claims priority to Korean Patent Application No.2008-87271, filed on Sep. 04, 2008, and all the benefits accruing therefrom under 35 U.S.C. §119, the contents of which in its entirety are herein incorporated by reference.

### BACKGROUND

1. Field

Disclosed herein is a dielectric paste having low dielectric loss, a method of preparing the dielectric paste and an article that uses the same.

2. Description of the Related Art

In order to reduce the size of an electronic apparatus or increase the speed of electronic circuitry, the embedding passive devices such as, for example, resistors, capacitors, inductors, and the like, in a printed circuit boards (PCB)is being undertaken in preference to mounting them on the PCB.

The technique of embedding them in the PCB enables wiring across the shortest distances and therefore reduces the surface area of the PCB, which in turn minimizes the weight of devices that use such PCBs. In addition, as the inductance of the substrate is decreased, electrical performance can be improved. In addition, the number of parts mounted on the substrate and the number of solder joints may be decreased, thus increasing mounting reliability and lowering assembly costs. An embedded capacitor generally uses a capacitance from about 1 picoFarad (“pF”) to about 1 microFarad (“μF”) or more, depending on the application. Thus, when a thin film process, for example, sputtering or chemical vapor deposition (CVD), is used, a high capacitance can be achieved due to the reduced thickness of the thin film. However, in the case where a thin film process is applied to an organic substrate, such as, for example, FR-4, or a flex substrate for commercial purposes, it may cause problems such as reduced performance at low temperatures, easy breakage of ceramic thin films when applied to an organic substrate. The drawbacks include high process cost.

In contrast, a thick film application process using a polymer resin that is disposed upon a glass substrate is simple and inexpensive and ensures reliable performance but the combination generally displays a low dielectric capacitance. Accordingly, many attempts have been made to disperse electrically conducting particles for example, metal or carbon in a thermosetting polymer matrix so that the concentration thereof reaches approximately the percolation threshold to achieve a high capacitance while at the same time resolving the aforementioned problems displayed by thin films while taking the advantage of the properties of thick films.

For instance, a method of forming an embedded structure can involve printing a resin composition paste containing a filler having a high dielectric constant (high-k) on the electrode thus forming a dielectric layer and then forming another electrode on the dielectric layer.

The paste generally contains a ceramic as the high dielectric constant k filler. In this case, the dielectric constant is merely tens of pF. In order to obtain a capacitor having a dielectric constant of hundreds of pF or more, a dielectric layer having a ceramic filler that has a much greater dielectric constant is desired. Since this is not always possible, it has been proposed to add a conductive material such as, for example, carbon black.

Such an ultra high dielectric constant k carbon black polymer composite may have ultra high dielectric constant (k) of greater than or equal to about 13,300 at 10 kHz using highly conductive carbon black, but also has a very high dielectric loss factor (Df) of greater than or equal to about 0.5. As a result of this high dielectric loss factor, it has not been commercialized. In summary, a thick film material having a high-dielectric constant (k) of greater than or equal to about 2000 and a dielectric loss of less than or equal to about 0.2 that would work effectively in the aforementioned applications has not been discovered.

### SUMMARY

Disclosed herein is a dielectric paste having a high dielectric constant (k) and low dielectric loss, with superior insulating properties. This is generally accomplished by preventing a dielectric loss in a high dielectric constant k composite having high dielectric loss.

Disclosed herein is a dielectric having high dielectric constant k and low dielectric loss, for example, a dielectric loss of about 0.2 or less, and an embedded capacitor using the same.

Disclosed herein is a method of effectively preparing a dielectric having low dielectric loss.

In one embodiment, a dielectric paste may include (A) a thermosetting resin; (B) an acid anhydride-based curing agent; (C) high dielectric constant particles; (D) an amine-based catalyst; and (E) a material for forming a salt with the amine-based catalyst (D).

As a result of research into dielectrics of high dielectric constant particles/thermosetting resin composites, it has been discovered that catalysts used to cure the thermosetting resin are poisoned due to adsorption that occurs on the surface of the high dielectric constant particles, and therefore the matrix is not sufficiently cured, thereby generating the leakage current. Disclosed herein therefore is a dielectric paste that prevents the catalyst from binding with the high dielectric constant particles, such as, for example, carbon black. As a result the matrix is sufficiently cured.

In the dielectric paste, the material (E) that undergoes bonding with the catalyst is used so that the catalyst may be introduced in the form of a salt thus preventing the catalyst from binding with the high dielectric constant particles. This prevents the poisoning of the catalyst during the curing process, with the result that the thermosetting resin achieves a high degree of cure. This high degree of cure prevents the generation of leakage current of the polymer matrix and thus minimizes the dielectric loss. It can therefore be used to produce an embedded capacitor having low dielectric loss.

An example of the thermosetting resin (A) may include a bisphenol type epoxy resin. The bisphenol type epoxy resin may have a structure of Formula 1 below, but is not limited thereto.

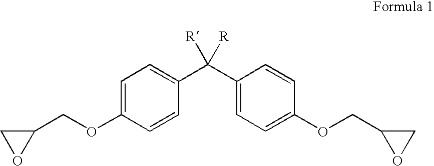

wherein R and R′ are each independently a C₁₋₆ alkyl group or a hydroxyl group (—OH).

Examples of the acid anhydride-based curing agent (B) may include succinic anhydride, maleic anhydride, dodecynyl succinic anhydride, phthalic anhydride (PA), tetrahydrophthalic anhydride (THPA), hexahydrophthalic anhydride (HHPA), methyl tetrahydrophthalic anhydride (Me-THPA), methyl hexahydrophthalic anhydride (Me-HHPA), trialkyl tetrahydrophthalic anhydride (TATHPA), methyl cyclohexanedicarboxylic anhydride (MCHDA), trimellitic anhydride, chlorendic anhydride, pyromellitic anhydride, benzophenone tetracarboxylic dianhydride and mixtures thereof.

Examples of the high dielectric constant particles (C) may include ceramics. Electrically conducting particles such as, for example, carbon black and carbon nanotubes may be added to the ceramics to increase the dielectric constant of the dielectric paste. The carbon black may be selected from the group consisting of Ketjen black, acetylene black, furnace black, oil black, Denka black, and Mitsubishi carbon black. These carbon blacks exhibit high conductivity and also exhibit superior dispersibility in a resin matrix.

The average particle size (D50) of the high dielectric constant particles (C) are about 5 nanometers (“nm”) to about 5 micrometers (“μm” ), taking into account their dispersibility and their miscibility in the matrix. The high dielectric constant particles may be subjected to surface treatment using a hydroxyl group-containing material, a carboxyl group-containing material, a silane-based material, a titanate-based material, or a combination comprising at least one of the foregoing materials.

The amine-based catalyst (D) may be a weak basic secondary amine. The weak basic secondary amine may be an imidazole-based catalyst. Examples of the imidazole-based catalyst are 1-methyl imidazole and its derivatives, 2-methyl imidazole and its derivatives, 2-ethyl 4-methyl imidazole and its derivatives, 2-phenyl imidazole and its derivatives, 2-cyclohexyl 4-methyl imidazole and its derivatives, 4-butyl 5-ethyl imidazole and its derivatives, 2-methyl 5-ethyl imidazole and its derivatives, 2-octyl 4-hexyl imidazole and its derivatives, 2,5-chloro-4-ethyl imidazole and its derivatives, 2-butoxy 4-allyl imidazole and a combination comprising at least one of the foregoing imidazole based catalysts.

The material (E) for forming a salt with the catalyst (D) may be weak acid having a pH of about 5 to about 7. Examples of the weak acid may include organic acids.

The organic acid may be selected from the group consisting of citric acid, oxalic acid, succinic acid, maleic acid, malonic acid, tartaric acid, phthalic acid, malic acid, glutaric acid, formic acid, acetic acid, oleic acid, propionic acid, butyric acid, valeic acid, acrylic acid, glycine, lactic acid, nicotinic acid, and a combination comprising at least one of the foregoing acids. Exemplary acids are oleic acid or propionic acid.

Alternatively, the material (E) may be selected from the group consisting of glycolic acid, lactic acid, 3-hydroxypropionic acid, α-hydroxyisobutyric acid, β-hydroxyisobutyric acid, malic acid, citric acid, tartaric acid, aminoacetic acid, 2-amino-propionic acid, 3-amino-propionic acid, 2-aminobutyric acid, glutamic acid, L-alanine, β-alanine, and a combination comprising at least one of the foregoing acids.

The material (E) may have a melting point lower than the curing temperature of the thermosetting resin (A) so that it is can separate from the catalyst during the curing process and may be volatilized.

In one exemplary embodiment, the dielectric paste may include, based on the total volume of the dielectric paste, about 40 to about 60 volume percent (“vol %”) of (A), about 20 to about 50 vol % of (B), about 1 to about 15 vol % of (C), about 0.1 to about 3 vol % of (D), and about 0.05 to about 3 vol % of (E).

The amount ratio (volume ratio) of (A) to (B) to (D) may be about 1:0.5:0.01 to about 1:1:0.05. Also, the amount ratio of (D) to (E) may be about 1:0.5 to about 1:1.5, and desirably about 1:1.

In addition, a dielectric may be obtained by curing the dielectric paste, and a capacitor may include the dielectric and a conductor. This capacitor may be embedded in a substrate and thus may be used in the form of an embedded capacitor.

In addition, a method of preparing the dielectric using the dielectric paste may include dispersing high dielectric constant particles (C) in a solvent, thus obtaining a first mixture; mixing a thermosetting resin (A), an acid anhydride-based curing agent (B), an amine-based catalyst (D), and a material (E) for forming a salt with the amine-based catalyst (D), thus obtaining a second mixture; blending the first mixture with the second mixture and then evaporating the solvent, thus preparing a dielectric paste; and heating the dielectric paste to a temperature of about 150 to about 200 degrees centigrade (C) from room temperature within about 10 to about 30 minutes (“min”) and then allowing the dielectric paste to stand at the temperature for about 1.5 to about 2 hours, thus curing the dielectric paste to form the dielectric.

In the method, (1) and (2) may be performed regardless of the sequence thereof. For example, (2) may be performed first, or (1) and (2) may be performed at the same time.

Also, when occasion demands, in (2), the amine-based catalyst (D) and the material (E) may be mixed first, thus forming a salt, which may then be mixed with the thermosetting resin (A) and the curing agent (B).

### BRIEF DESCRIPTION OF THE DRAWING

Exemplary embodiments will be more clearly understood from the following detailed description taken in conjunction with the accompanying drawing, in which:

FIG. 1 is a graph of thermogravimetric analysis (TGA) of a dielectric paste.

### DETAILED DESCRIPTION

Hereinafter, a detailed description will be given of exemplary embodiments with reference to the accompanying drawing.

Aspects, advantages, and features of the present invention and methods of accomplishing the same may be understood more readily by reference to the following detailed description of preferred embodiments and the accompanying drawings. The present invention may, however, may be embodied in many different forms, and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

It will be understood that when an element or layer is referred to as being “on” or “connected to” another element or layer, the element or layer can be directly on or connected to another element or layer or intervening elements or layers. In contrast, when an element is referred to as being “directly on” or “directly connected to” another element or layer, there are no intervening elements or layers present. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer, or section from another region, layer or section. Thus, a first element, component, region, layer, or section discussed below could be termed a second element, component, region, layer, or section without departing from the teachings of the present invention.

Spatially relative terms, such as “below”, “lower”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “lower” relative to other elements or features would then be oriented “above” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in detail with reference to the accompanying drawings. However, the aspects, features, and advantages of the present invention are not restricted to the ones set forth herein. The above and other aspects, features and advantages of the present invention will become more apparent to one of ordinary skill in the art to which the present invention pertains by referencing a detailed description of the present invention given below.

In one exemplary embodiment, a dielectric paste includes (A) a thermosetting resin, (B) an acid anhydride-based curing agent, (C) high dielectric constant particles, (D) an amine-based catalyst, and (E) a material for forming a salt with the amine-based catalyst (D).

In general, in a polymer matrix, high dielectric constant particles, for example, carbon black may be bound with an amine-based catalyst. The basic amine-based catalyst may be adsorbed on the surface of acidic carbon black and thus may not be sufficiently activated in the curing process, thereby reducing the degree of curing of the matrix and generating a leakage current.

In one embodiment, when the material (E) binding with the catalyst is added to the dielectric paste, the catalyst may be introduced in the form of a salt, thus preventing the catalyst from binding with the high dielectric constant particles, thereby prohibiting the poisoning of the catalyst used in the curing process, achieving a high degree of cure, and preventing the generation of a leakage current. The thermosetting resin (A) may include an epoxy resin, a phenolic resin, an unsaturated polyester resin, a vinyl ester resin, a polyimide (PI) resin, a polyphenylene ether oxide (PPO) resin, a bismaleimidetriazine cyanate ester resin, a fumarate resin, a polybutadiene resin, a polyvinyl benzyl ether resin, and a combination comprising at least one of the foregoing resins. Examples of the thermosetting resin may also include phenolic resins, including novolac type phenolic resin for example a phenol novolac resin, a cresol novolac resin, a bisphenol A novolac resin, and a resol type phenol resin; an epoxy resin, including a bisphenol type epoxy resin such as, for example, a bisphenol A epoxy resin and a bisphenol F epoxy resin, a novolac type epoxy resin for example a novolac epoxy resin and a cresol novolac epoxy resin, a biphenyl type epoxy resin, and a diphenyl ether type epoxy resin; a triazine-based resin, including a urea resin and a melamine resin; an unsaturated polyester resin; a bismaleimide resin; a polyurethane resin; an diallyl phthalate resin; a silicone resin; a resin having a benzoxadine ring; a cyanate ester resin; and a resin having a methacryloyl group.

Among them, the bisphenol type epoxy resin permits the use of a wide variety of curing agents and controlling agents. It also reduces the generation of volatile materials upon curing, reduces shrinkage, exhibits a very high resistance to chemical materials or chemical solvents and exhibits superior adhesion between the thermosetting resin and additives that are added to the thermosetting resin.

In one exemplary embodiment, the thermosetting resin (A) may be a bisphenol type epoxy resin.

Examples of the bisphenol type epoxy resin may include compounds having two or more epoxy groups per one molecule, including a bisphenol A epoxy resin, a hydrogenated bisphenol A epoxy resin, a bisphenol F epoxy resin, a bisphenol A novolac epoxy resin, and a bisphenol S epoxy resin.

In the exemplary embodiment, the bisphenol type epoxy resin may have a structure of Formula 1 below.

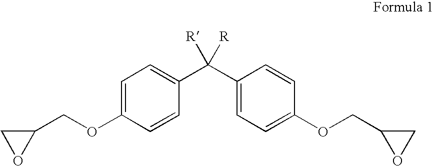

where R and R′ are each independently a C₁₋₆ alkyl group or a hydroxyl group (—OH).

If the molecular weight of the thermosetting resin is too small, the solidification of the paste may occur at lower temperatures. Conversely, if the molecular weight thereof is too large, the paste may be highly viscous and thus may be difficult to handle. In order to have a dielectric paste that has workable properties, the thermosetting resin may have a number average molecular weight from about 300 grams per mole (g/mol) to about 8000 g/mol, and specifically from about 300 g/mol to about 3000 g/mol.

The heat curing agent (B) may include acid anhydride-based curing agent having high heat resistance. Examples of a suitable acid anhydride-based curing agent are those selected from the group consisting of succinic anhydride, maleic anhydride, dodecynyl succinic anhydride, phthalic anhydride (PA), tetrahydrophthalic anhydride (THPA), hexahydrophthalic anhydride (HHPA), methyl tetrahydrophthalic anhydride (Me-THPA), methyl hexahydrophthalic anhydride (Me-HHPA), trialkyl tetrahydrophthalic anhydride (TATHPA), methyl cyclohexanedicarboxylic anhydride (MCHDA), trimellitic anhydride, chlorendic anhydride, pyromellitic anhydride, benzophenonetetracarboxylic dianhydride, methyl hymic anhydride (MHAC), and a combination comprising at least one of the foregoing acid anhydride-based curing agents.

Exemplary acid anhydride-based curing agents are Me-THPA, Me-HHPA, and MHAC (methyl hymic anhydride). These exemplary acid anhydride-based curing agents are liquids having low viscosity at room temperature and may thus be desirably used for easy workability. HHPA is a white solid having a low melting point and high reactivity and may facilitate the curing of the thermosetting resin within a short time.

The high dielectric constant particles (C) may have a relative dielectric constant and a Q value (reciprocal of the dielectric tangent) greater than those of the thermosetting resin at a high frequency, and may have high dielectric constant k from about 10 to about 30,000.

Examples of the high dielectric constant particles may include ceramic powders. Examples of the ceramic powder may include Mg₂SiO₄, Al₂_{O}₃, MgTiO₃, ZnTiO₃, Zn₂TiO₄, TiO₂, CaTiO₃, SrTiO₃, SrZrO₃, BaTi₂O₅, BaTi₄O₉, Ba₂Ti₉O₂₀, Ba₂(Ti,Sn)₉O₂₀, ZrTiO₂, (Zr,Sr)TiO₄, BaNd₂Ti₅O₁₄, BaSm₂TiO₁₄, Bi₂O₃BaONd₂O₃TiO₂, PbOBaONd₂O₃TiO₂, (Bi₂O₃, PbO)BaONd₂O₃TiO₂, La₂Ti₂O₇, Nd₂Ti₂O₇, (Li,Sm)TiO₃, Ba(Mg_{1/3}Ta_{2/3})O₃, Ba(Zn_{1/3}Ta_{2/3})O₃, Ba(Zn_{1/3}Nd_{2/3})O₃, and Sr(Zn_{1/3}Nd_{2/3})O₃, and a combination comprising at least one of the foregoing ceramic powder. Examples of the ceramic powder having high dielectric constant k of about greater than or equal to about 1,000 may include BaTiO₃, (Ba,Pb)TiO₃, Ba(Ti,Zr)O₃, and (Ba,Sr)TiO₃.

Materials that may be added to the ceramic powder to increase the dielectric constant are electrically conducting particles such as, for example, carbon fibers, graphite, carbon black, carbon nanotubes and a combination comprising at least one of the foregoing electrically conducting particles. The carbon black is electrically conductive. Examples of carbon black are Ketjen black, acetylene black, furnace black, oil black, Denka black, and Mitsubishi carbon black. The use of Ketjen black having high dielectric constant k is desirable.

If the particle size of the high dielectric constant particles (C) is too small, the aggregation of the particles may occur, the surface area may be excessively increased, and a packing factor may be decreased. Conversely, if the particle size is too large, the particles may be precipitated in the paste and uniform dispersion of these particles becomes difficult. It is therefore desirable for the high dielectric constant particles to have an average particle size (D50) from about 5 nanometers (“nm”) to about 10 micrometers (“μm”).

In the case where carbon black is to produce the high dielectric constant particles (C), it is desirable for the carbon black to be acidic. Such acidic characteristics may be provided to the carbon black by the presence of functional groups such as, for example, a carboxyl group (—COOH) or a hydroxyl group (—OH) on the surface. The presence of these acidic functional groups promotes the adsorption of basic amine-based catalysts onto the surface of the carbon black. Surface-modified carbon black may therefore be used, and for instance, the surface of carbon black may be coated with an epoxy group-containing compound, an acid anhydride-based compound, or an ester group-containing compound. The treatment of the carbon black with the aforementioned compounds prevents the aggregation of carbon black, and the electrical conductivity of the dielectric may be eliminated.

When occasion demands, in order to improve miscibility of the dielectric particles with the thermosetting resin that constitutes the matrix, surface treatment of the ceramic particles may be performed. In order to improve dispersibility, surface treatment may be conducted using a stabilizer, if desired.

In order to prevent the formation of an electrically conductive path along the surface of the dielectric, a surface treatment of the dielectric particles may be performed by using an insulating material. Surface treatment of the ceramic particles or of the electrically conducting particles may be carried out using a hydroxyl group-containing material, a carboxyl group-containing material, a silane-based material, or a titanate-based material.

In addition, the catalyst (D) may be added to improve the heat curability of the thermosetting resin. For example when the thermosetting resin comprises an epoxy resin, an amine-based catalyst may be used. The combination of an epoxy resin and an amine-based catalyst provides a dielectric that is economical and thermally stable at room temperature.

Examples of the amine-based catalyst may include aliphatic or aromatic secondary amines, including dimethylamine, diethylamine, dipropylamine, di-n-butylamine, sec-dipropylamine, dibenzylamine, dicyclohexylamine, diethanolamine, ethylmethylamine, methylpropylamine, arylethylamine, methylcyclohexylamine, morpholine, methyl-n-butylamine, ethylisopropylamine, benzylmethylamine, octylbenzylamine, octyl-chlorobenzylamine, methyl(phenylethyl)amine, benzylethylamine, di(chlorophenylethyl)amine, 1-methylamino-4-pentyne, pyridine, methylpyridine, 4-dimethylamino pyridine piperidine, and a combination comprising at least one of the foregoing amine based catalysts. An exemplary catalyst is an imidazole-based catalyst.

Examples of the imidazole-based catalyst may include 1-methyl imidazole, 2-methyl imidazole, 2-ethyl 4-methyl imidazole, 2-phenyl imidazole, 2-cyclohexyl 4-methyl imidazole, 4-butyl 5-ethyl imidazole, 2-methyl 5-ethyl imidazole, 2-octyl 4-hexyl imidazole, 2,5-chloro-4-ethyl imidazole, 2-butoxy 4-allyl imidazole, and a combination comprising at least one of the foregoing imidazole catalysts. An exemplary imidazole-based catalyst is 1-methyl imidazole or 2-phenyl imidazole. These imidazole-based catalysts have a high reaction stability and are inexpensive.

The material (E) for forming a salt with the amine-based catalyst (D) may facilitate the capping of the functional group of the catalyst (D) so that the catalyst (D) may be prevented from binding with the high dielectric constant particles. Further, the curing rate may be easily controlled through the addition of the material (E), and the material (E) may function to retard the rate of curing.

The material (E) may form an ionic bond with the amine-based catalyst (D), thus forming a salt. The material (E) may be a weak acid having a pH from about 5 to about 7 so that it may be subjected to an acid-base reaction with the basic catalyst (D) to thus form a salt.

Examples of the weak acid may include organic acids. Examples of the organic acid may be citric acid, oxalic acid, succinic acid, maleic acid, malonic acid, tartaric acid, phthalic acid, malic acid, glutaric acid, formic acid, acetic acid, oleic acid, propionic acid, butyric acid, valeic acid, acrylic acid, glycine, lactic acid, nicotinic acid, and a combination comprising at least one of the foregoing weak acids.

If the binding of the material (E) with the catalyst (D) is maintained even in a thermally cured state, the catalyst (D) may be inactivated and may prevent the curing of the entire thermosetting resin. The material (E) is therefore volatilized in the curing process so that it does not remain in the finally cured product.

It is to be noted that, the amounts of respective components are not limited and may be appropriately adjusted so as to exhibit various properties depending on the application.

For example, the dielectric paste may include, based on the total volume of the dielectric paste, about 40 to about 60 volume percent (vol %) of (A), about 20 to about 50 vol % of (B), about 1 to about 15 vol % of (C), about 0.1 to about 3 vol % of (D), and about 0.05 to about 3 vol % of (E).

The volume ratio of (A) to (B) to (D) may be about 1:0.5:0.01 to about 1:1:0.05.

The amount of (C) may be appropriately set depending upon the desired dielectric constant. If the added amount is too large, the density of the resin composition may be lowered, and the dielectric loss tangent may be increased. It is therefore desirable to use (C) in an amount of about 1 vol %o to about 15 vol %, based on the volume of the dielectric paste.

If the amount of the catalyst (D) is too small, the catalytic activity may be too low and the curing rate may also be too low. Conversely, if the amount of the catalyst (D) is too large, the shelf life of the dielectric paste is decreased, the storage stability of the dielectric paste is low and the curing rate may be excessively increased when forming the dielectric. In order to prevent this, the catalyst (D) may be used in an amount from about 0.1 vol % to about 3 vol %, based on the volume of the dielectric paste. The material (E), which forms a salt with the catalyst (D) to prevent the binding with the high dielectric constant particles may be added to the dielectric paste in an amount that corresponds to the amount of the catalyst (D). The volume ratio of (D) to (E) may be about 1:0.5 to about 1:1.5, and is desirably about 1:1.

Additionally, the dielectric paste may include various additives, as desired. Examples of additives include a diluent for lowering the viscosity of the paste, a thermoplastic resin for improving adhesiveness of the thermosetting resin with the high dielectric constant particles, and a dispersant for preventing the aggregation of the high dielectric constant particles and enabling a uniform dispersion of the high dielectric constant particles.

In one embodiment, a dielectric is manufactured from the dielectric paste.

The dielectric is manufactured by heating the dielectric paste to an elevated temperature of about 150 to about 200 degrees centigrade (° C.) from room temperature within about 10 to about 30 minutes and allows the dielectric paste to stay at the elevated temperature for about 1.5 to about 2 hours, thus curing it. By manufacturing the dielectric in this manner, poisoning of the catalyst is prevented and the thermosetting resin undergoes a high degree of curing, ultimately minimizing the generation of leakage current in the dielectric.

As the curing temperature and time are increased, the dielectric loss is greatly reduced because of effective curing of the thermosetting reins. The curing process may be performed by increasing the temperature to about 190 about 200° C. and then maintaining the increased temperature for a time period of greater than or equal to about 2 hours.

The dielectric may have a dielectric constant (Dk) of greater than or equal to about 3900 or more and dielectric loss (Df) of less than or equal to about 0.2 at a frequency of about 10 kHz.

The dielectric paste may be applied to a substrate by processes that include tape coating, screen printing, ink jetting, roll coating, spin coating, or a combination comprising at least one of the foregoing processes. The dielectric paste may then be cured to a dry state.

In one embodiment, an embedded capacitor may include the dielectric of the disclosure and a conductor, thus exhibiting a high dielectric constant k and a low dielectric loss factor. Thus, the embedded capacitor may be used for thick films or RF modules. A substrate including the embedded capacitor may be applied to devices for example WiMax RE modules or transceiver B/B chip sets.

In one embodiment, a method of preparing a dielectric using the dielectric paste may comprise dispersing the high dielectric constant particles (C) in a solvent, thus obtaining a first mixture; mixing a thermosetting resin (A), an acid anhydride-based curing agent (B), an amine-based catalyst (D), and a material (E) for forming a salt with the amine-based catalyst (D), thus obtaining a second mixture; blending the first mixture with the second mixture and then evaporating the solvent, thus preparing a dielectric paste, and heating the dielectric paste to a temperature of about 150 to about 200° C. from room temperature within about 10 to about 30 minutes and then allowing the dielectric paste to stand at the increased temperature for about 1.5 to about 2 hours, thus curing the dielectric paste.

In order to effectively prevent the binding of the high dielectric constant particles and the catalyst, the amine-based catalyst and the material (E) may be mixed separately from the dispersion of the high dielectric constant particles. As a result, the catalyst in the form of a salt may then be blended with the high dielectric constant particles. This prevents the catalyst from binding with the high dielectric constant particles, thus increasing the activity of the catalyst, resulting in a dielectric having a high degree of cure.

The formation of the first mixture and the second mixture, as detailed above, may be conducted simultaneously or sequentially, if desired. In the formation of the second mixture, the catalyst (D) may be mixed with the material (E), thus forming the salt, which may then be mixed with the thermosetting resin and the curing agent. The dielectric paste obtained by blending the first mixture with the second mixture may be subjected to the thermal curing process prior to or after being applied to a desired substrate.

A better understanding of the exemplary embodiments will be described in more detail with reference to the following examples. However, these examples are provided merely for the purpose of illustration and are not to be construed as limiting the scope of the embodiments disclosed herein.

### EXAMPLE 1

### 1-1. Preparation of Dielectric Paste

0.308 grams (g) of carbon black having an average particle size of about 10 to about 20 nm (available from Mitsubishi, 2300 ‘M’) and an ethyl acetate solvent were placed in a vessel, and then dispersed through ultrasonication for about 20 to about 30 minutes. Separately, in another vessel, about 2.127 g of DGEBA (diglycidyl ether of bisphenol A), about 0.964 g of HHPA (hexahydrophthalic anhydride), about 0.015 g of 1-methyl imidazole, and about 0.015 g of propionic acid are placed and then mixed using a magnetic stirrer for about 30 minutes or longer. The respective solutions are blended together and then additionally dispersed using a magnetic stirrer for about 30 minutes or longer. Thereafter, evaporation was performed, thus obtaining a dielectric paste.

### 1-2. Formation of Test Sample

The dielectric paste obtained in 1-1 is applied on a gold (Ag)-plated silicon wafer through tape printing, heated to about 160° C. from room temperature at a heating rate of about 10° C./min (degrees Centigrade per minute), allowed to stand at about 160° C. for about 1.5 hours, and then cooled under ambient conditions, thus manufacturing an embedded capacitor sample.

### EXAMPLE 2

This sample was manufactured in the same manner as in Example 1, with the exception that, in 1-2, the dielectric paste is heated to about 190° C. from room temperature at a heating rate of about 10° C./min, allowed to stand at about 190° C. for about 2 hours, and then naturally cooled.

### COMPARATIVE EXAMPLE 1

This comparative sample was manufactured in the same manner as in Example 1, with the exception that propionic acid was not used.

### COMPARATIVE EXAMPLE 2

This comparative sample was manufactured in the same manner as in Comparative Example 1, with the exception that the dielectric paste of Comparative Example 1 is heated to about 190° C. from room temperature at a heating rate of about 10° C./min, allowed to stand at about 190° C. for about 2 hours, and then naturally cooled.

### EXPERIMENTAL EXAMPLE 1

Two samples of each of Examples 1 and 2 and Comparative Examples 1 and 2 were subjected to tests to determine the dielectric properties through an metal-insulator-metal (“MIM”) method at 1 MHz. The results are shown in Table 1 below.

TABLE 1

| | Curing | | Dielectric | Dielectric |
|---|---|---|---|---|
| | Conditions | | Constant | Loss (%) |
| Ex. 1 | 160° C., 1.5 hrs | 1^{st} | 68.2 | 56.7 |
| | | 2^{nd} | 61.8 | 45.7 |
| Ex. 2 | 190° C., 2 hrs | 1^{st} | 32.2 | 15.8 |
| | | 2^{nd} | 32.4 | 19.0 |
| C. Ex. 1 | 160° C., 1.5 hrs | 1^{st} | 386 | 100.3 |
| | | 2^{nd} | 670 | 105.1 |
| C. Ex. 2 | 190° C., 1.5 hrs | 1^{st} | 202 | 106.7 |
| | | 2^{nd} | 203 | 105.4 |

It is to be noted that the dielectric loss can be expressed as a percentage or as a number. For example, a dielectric loss of 0.2 can also be expressed as 20%. The dielectric loss is the loss of energy that manifests itself as a rise in temperature of the dielectric material, when it is placed in an alternating electric field.

### EXPERIMENTAL EXAMPLE 2

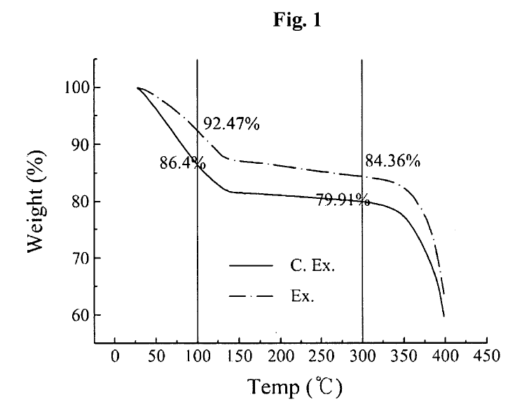

The dielectric paste containing propionic acid and the dielectric paste containing no propionic acid in the examples and comparative examples were subjected to thermogravimetric analysis (“TGA”) for weight reduction depending on the temperature. The graph of TGA thereof is shown in the FIG. 1.

As is apparent from Table 1, the samples of Comparative Examples 1 and 2 in which the 1-methyl imidazole catalyst is used alone had very high dielectric loss of about 100. However, the samples of Examples 1 and 2 using propionic acid could be seen to have dielectric loss considerably reduced by at least about 50%.

This improvement occurs because the poisoning of the catalyst is prevented due to the addition of propionic acid, thus increasing the degree of curing of the thermosetting resin, thereby effectively eliminating leakage current in the matrix.

In the sample of Example 2 resulting from the process at about 190° C. for about 2 hours, the dielectric loss is greatly reduced below about 20%. As the temperature of the process is increased, the additional crosslinking of the thermosetting resin due to the addition of propionic acid results in a dielectric that has a lower dielectric loss factor.

From the graph of TGA of FIG. 1, the pyrolysis rate for the sample containing the propionic acid can be seen to be lower than that for the case where propionic acid is not added. This shows that thermal stability is increased with the addition of the propionic acid.

In summary, a catalyst may be used in the form of a salt with the material (E), thus preventing the catalyst from binding with high dielectric constant particles. This activates the catalyst during the curing process, thus facilitating the production of a dielectric that has a high degree of cure. This reduces the generation of a leakage current, resulting in a dielectric having a high dielectric constant k and low dielectric loss factor.

Although exemplary embodiments have been disclosed for illustrative purposes, those skilled in the art will appreciate that various modifications, additions and substitutions are possible, without departing from the scope and spirit of the invention as disclosed in the accompanying claims.

What is claimed is:

1. A dielectric paste, comprising:
(A) a thermosetting resin;
(B) an acid anhydride-based curing agent;
(C) high dielectric constant particles;
(D) an amine-based catalyst; and
(E) a material for forming a salt with the amine-based catalyst (D).

2. The dielectric paste of claim 1, wherein the thermosetting resin (A) is a bisphenol type epoxy resin.

3. The dielectric paste of claim 2, wherein the bisphenol type epoxy resin has a structure of Formula 1 below: 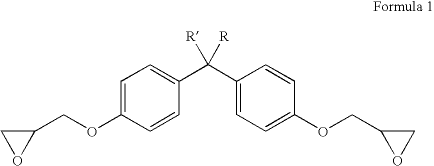
where R and R′ are each independently a C₁₋₆ alkyl group or a hydroxyl group (—OH).

4. The dielectric paste of claim 1, wherein the high dielectric constant particles (C) are ceramics.

5 The dielectric paste of claim 1, wherein the high dielectric constant particles can further comprise electrically conducting particles; the electrically conducting particles being carbon nanotubes, carbon black, or a combination comprising at least one of the foregoing electrically conducting particles.

6. The dielectric paste of claim 1, wherein the high dielectric constant particles (C) have an average particle size (D50) from about 5 nanometers to about 5 micrometers.

7. The dielectric paste of claim 1, wherein the high dielectric constant particles (C) are subjected to surface treatment using a hydroxyl group-containing material, a carboxyl group-containing material, a silane-based material, or a titanate-based material.

8. The dielectric paste of claim 1, wherein the amine-based catalyst (D) is a weak basic secondary amine.

9. The dielectric paste of claim 8, wherein the weak basic secondary amine is an imidazole-based catalyst.

10. The dielectric paste of claim 1, wherein the material (E) is a weak acid having a pH from about 5 to about 7.

11. The dielectric paste of claim 10, wherein the weak acid is an organic acid.

12. The dielectric paste of claim 1, wherein a volume ratio of (A) to (B) to (D) is 1:0.5:0.01 to about 1:1:0.05.

13. The dielectric paste of claim 1, wherein the high dielectric constant particles (C) are used in an amount from about 1 vol % to about 15 volume percent based on a total volume of the dielectric paste.

14. The dielectric paste of claim 1, wherein a volume ratio of (D) to (E) is about 1:0.5 to about 1:1.5.

15. A dielectric, obtained by curing the dielectric paste of claim 1.

16. A capacitor, comprising the dielectric of claim 15 and a conductor; the dielectric being in contact with the conductor.

17. A substrate, in which the capacitor of claim 16 is embedded.

18. A dielectric paste, comprising:
(A) a thermosetting resin;
(B) an acid anhydride-based curing agent;
(C) high dielectric constant particles; the particles having a dielectric constant of about 10 to about 30,000;
(D) an amine-based catalyst; and
(E) a material for forming a salt with the amine-based catalyst (D); where the material for forming a salt with the amine based catalyst is propionic acid.

19. A method of preparing a dielectric comprising:
dispersing high dielectric constant particles (C) in a solvent, thus obtaining a first mixture;
mixing a thermosetting resin (A), an acid anhydride-based curing agent (B), an amine-based catalyst (D), and a material (E) for forming a salt with the amine-based catalyst (D), thus obtaining a second mixture;
blending the first mixture with the second mixture;
evaporating the solvent, thus preparing a dielectric paste; and
heating the dielectric paste to a temperature of about 150 to about 200° C. from room temperature within a time period of up to about 30 minutes;
retaining the dielectric paste at the temperature of about 150 to about 200° C. for about 1.5 to about 2 hours, thus curing the dielectric paste.

20. The method of claim 19, wherein the mixing the thermosetting resin (A), the acid anhydride-based curing agent (B), the amine-based catalyst (D), and the material (E) is performed by mixing the amine-based catalyst (D) and the material (E), thus forming a salt, which is then mixed with the thermosetting resin (A) and the curing agent (B).
